(19) United States
(12) Patent Application Publication
(10) Pub. No.: US 2025/0174291 A1
(43) Pub. Date: May 29, 2025

(54) Memory apparatus having at-speed test mechanism and memory test method of the same

(71) Applicant: REALTEK SEMICONDUCTOR CORPORATION, Hsinchu (TW)

(72) Inventors: YU-CHENG LO, Hsinchu (TW); CHUN-YI KUO, Hsinchu (TW)

(21) Appl. No.: 18/948,580

(22) Filed: Nov. 15, 2024

(30) Foreign Application Priority Data
Nov. 27, 2023 (TW) 112145879

(51) Int. Cl. G11C 29/10

(52) U.S. Cl. CPC G11C 29/10

(57) ABSTRACT

The present disclosure discloses a memory apparatus having at-speed test mechanism. An output function circuit block receives an output signal from a memory circuit to generate an output result. A signal feeding circuit block includes a feeding flip-flop circuit, a feeding logic circuit and a feeding multiplexer. The feeding flip-flop circuit receives and outputs a feeding signal. The feeding logic circuit receives and processes the feeding signal to generate a processed control signal. The feeding multiplexer is electrically coupled to the feeding flip-flop circuit and the feeding logic circuit. In an at-speed test mode, a test pattern is written to the memory circuit and the feeding multiplexer selects the feeding signal to be a feeding control signal to operate the memory circuit to directly control the memory circuit to output the test pattern in the output signal such that the output result is verified to perform an output at-speed test.

### BACKGROUND OF THE INVENTION

### 1. Field of the Invention

The present disclosure relates to a memory apparatus having at-speed test mechanism and a memory test method of the same.

### 2. Description of Related Art

In order to improve the quality of the manufactured semiconductors, semiconductor manufacturers and integrated circuit designers needs the perform test on the semiconductor products to make sure that the flaws in the semiconductor products can be reduced. An efficient test method may accomplish a greater improvement of the quality of the products.

A common memory apparatus test method is to perform test on a memory input/output interface that includes an input function circuit and an output function circuit by using the scan test. However, the memory circuit is bypassed when the scan test is performed. As a result, an at-speed test is not able to be performed on the actual signal transmission path of the output function circuit.

### SUMMARY OF THE INVENTION

In consideration of the problem of the prior art, an object of the present disclosure is to provide a memory apparatus having at-speed test mechanism and a memory test method of the same.

The present invention discloses a memory apparatus having at-speed test mechanism that includes a memory circuit, an output function circuit block and a signal feeding circuit block. The output function circuit block is configured to receive and process an output signal from the memory circuit to generate an output result. The signal feeding circuit block includes a feeding flip-flop circuit, a feeding logic circuit and a feeding multiplexer. The feeding flip-flop circuit is configured to receive and output a feeding signal. The feeding logic circuit is electrically coupled to the feeding flip-flop circuit to receive and process the feeding signal to generate a processed control signal. The feeding multiplexer is electrically coupled to the feeding flip-flop circuit and the feeding logic circuit. In an output at-speed test mode, a plurality of test patterns are written to the memory circuit, the feeding multiplexer is configured to select the feeding signal to be a feeding control signal to operate the memory circuit to directly control the memory circuit to output the test patterns in the output signal such that the output result is verified to perform an output at-speed test.

The present invention also discloses a memory test method having at-speed test mechanism that includes steps outlined below. A plurality of test patterns are written to a memory circuit in an output at-speed test mode. A feeding signal is received and outputted by a feeding flip-flop circuit included by a signal feeding circuit block, wherein a feeding logic circuit included by the signal feeding circuit block is electrically coupled to the feeding flip-flop circuit to receive and process the feeding signal to generate a processed control signal. The feeding signal is selected to be a feeding control signal to operate the memory circuit to directly control the memory circuit to output the test patterns in the output signal by a feeding multiplexer included by the signal feeding circuit block and electrically coupled to the feeding flip-flop circuit and the feeding logic circuit. The output signal is received and processed from the memory circuit by an output function circuit block to generate an output result such that the output result is verified to perform an output at-speed test.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1 illustrates a block diagram of a memory apparatus having at-speed test mechanism and a test patterns generation circuit to perform test on the memory apparatus according to an embodiment of the present invention.

FIG. 2 illustrates a more detailed block diagram of the memory circuit according to an embodiment of the present invention.

FIG. 3 illustrates a flow chart of a memory test method according to an embodiment of the present invention.

### DETAILED DESCRIPTION OF THE PREFERRED EMBODIMENTS

An aspect of the present invention is to provide a memory apparatus having at-speed test mechanism and a memory test method of the same to treat a memory circuit as a buffer to write test patterns thereto, bypass a feeding logic circuit by using a feeding multiplexer of a signal feeding circuit block and directly output a feeding signal through a feeding flip-flop circuit to control the memory circuit to output the test patterns in an output signal. An output result generated according to the output signal by an output function circuit block is further verified to accomplish the output at-speed test.

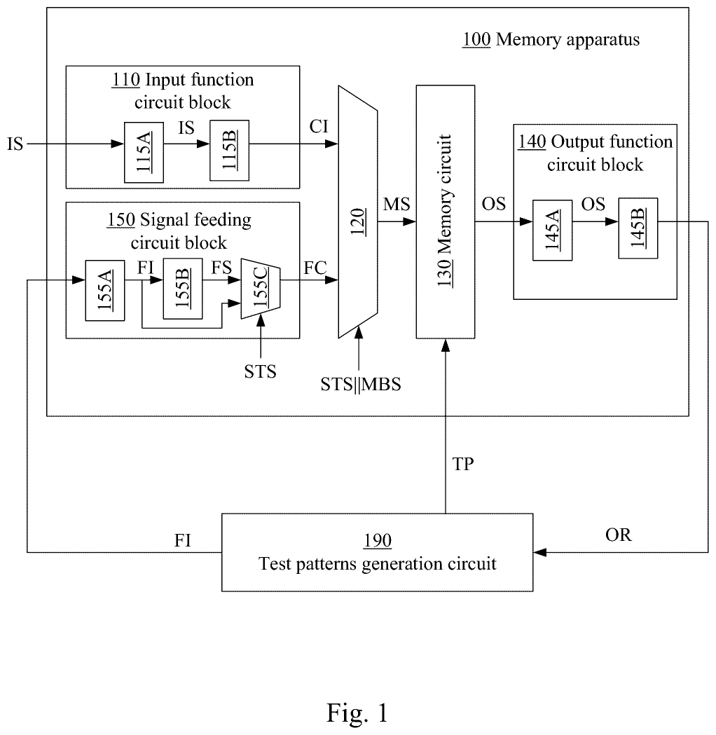

Reference is now made to FIG. 1. FIG. 1 illustrates a block diagram of a memory apparatus 100 having at-speed test mechanism and a test patterns generation circuit 190 to perform test on the memory apparatus 100 according to an embodiment of the present invention.

In an embodiment, the memory apparatus 100 can be such as, but not limited to a static random-access memory (SRAM). Depending on different requirements, the memory apparatus 100 may operate in different modes.

For example, the memory apparatus 100 may operate in a memory operation mode so as to be accessed (either read or written) by other components. The memory apparatus 100 may also operate in a scan test mode to perform a scan test. The memory apparatus 100 may further operate in an output at-speed test mode to perform an output at-speed test.

The memory apparatus 100 includes an input function circuit block 110, an input selection multiplexer 120, a memory circuit 130, an output function circuit block 140 and a signal feeding circuit block 150.

The input function circuit block 110 is configured to generate an input control signal CI to control the memory circuit 130 that actually stores data.

In an embodiment, the input function circuit block 110 includes an input flip-flop circuit 115A and an input logic circuit 115B. The input flip-flop circuit 115A is configured to receive an input signal IS. The input logic circuit 115B receives and processes the input signal IS through the input flip-flop circuit 115A to generate the input control signal CI.

In the memory operation mode, the input signal IS is generated by a component that accesses the memory apparatus 100 (e.g., a processor of a computer system that the memory apparatus 100 is disposed). The input signal IS is processed by the input function circuit block 110 to generate the input control signal CI to access the memory circuit 130.

In the scan test mode, the input signal IS is generated by such as, but not limited to the test patterns generation circuit 190. The input signal IS is processed by the input function circuit block 110 to generate the input control signal CI to perform the scan test on the memory circuit 130.

The input selection multiplexer 120 is configured to perform selection among different signal sources according to different modes to generate a memory control signal MS. In an embodiment, the input selection multiplexer 120 selects the input control signal CI generated by the input function circuit block 110 as the memory control signal MS in the memory operation mode or the scan test mode to operate the memory circuit 130.

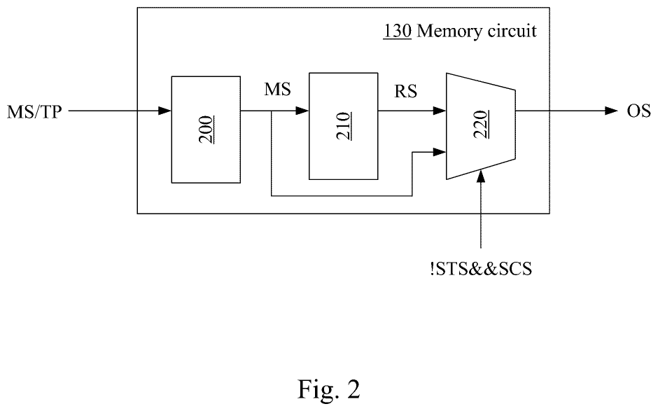

Reference is now made to FIG. 2. FIG. 2 illustrates a more detailed block diagram of the memory circuit 130 according to an embodiment of the present invention. In an embodiment, the memory circuit 130 is an integrated test memory and includes a scan flip-flop circuit 200, a memory array 210 and a memory multiplexer 220.

The scan flip-flop circuit 200 may be connected differently in the memory operation mode and the scan test mode and is configured to receive and output the memory control signal MS.

The memory array 210 is electrically coupled to the scan flip-flop circuit 200, is configured to receive the memory control signal MS through the scan flip-flop circuit 200 and generates a read signal RS when a read operation is performed on the memory array 210.

The memory multiplexer 220 is electrically coupled to the scan flip-flop circuit 200 and the memory array 210. The memory multiplexer 220 is configured to select the read signal RS as an output signal OS in the memory operation mode. The memory multiplexer 220 is further configured to select the memory control signal MS outputted by the scan flip-flop circuit 200 as the output signal OS in the scan test mode. As a result, the memory array 210 is equivalently bypassed by the memory multiplexer 220 in the scan test mode.

The output function circuit block 140 is configured to receive and process the output signal OS from the memory circuit 130 to generate an output result OR.

In an embodiment, the output function circuit block 140 includes an output logic circuit 145A and an output flip-flop circuit 145B. The output logic circuit 145A is configured to receive and process the output signal OS to generate the output result OR. The output flip-flop circuit 145B is configured to receive and output the output result OR.

In an embodiment, the scan test performed in the scan test mode includes a functional test configured to test the functions of the input logic circuit 115B included by the input function circuit block 110 and the functions of the output logic circuit 145A included by the output function circuit block 140.

Ideally, the scan test also includes at-speed test configured to test the input function circuit block 110 and the output function circuit block 140, especially the signal transition speed of the input logic circuit 115B and the output logic circuit 145A.

Since the memory circuit 130 is an integrated test memory, the observation from the memory circuit 130 to the input logic circuit 115B is the same as the signal processing path of the input logic circuit 115B. However, since the memory array 210 is equivalently bypassed by the memory multiplexer 220 in the scan test mode, the real signal processing path of the output logic circuit 145A is not presented. As a result, the scan test can only perform the input at-speed test corresponding to the input logic circuit 115B of the input function circuit block 110 and is able not to perform the output at-speed test corresponding to the output logic circuit 145A of the output function circuit block 140.

In order to perform the output at-speed test of the output function circuit block 140, the signal feeding circuit block 150 is disposed in the memory apparatus 100 to perform the output at-speed test on the output function circuit block 140 in the output at-speed test mode.

The signal feeding circuit block 150 includes a feeding flip-flop circuit 155A, a feeding logic circuit 155B and a feeding multiplexer 155C.

The feeding flip-flop circuit 155A is configured to receive and output a feeding signal FI. The feeding logic circuit 155B is electrically coupled to the feeding flip-flop circuit 155A to receive and process the feeding signal FI to generate a processed control signal FS. The feeding multiplexer 155C is electrically coupled to the feeding flip-flop circuit 155A and the feeding logic circuit 155B to select one of the feeding signal FI and the processed control signal FS to be a feeding control signal FC according to different modes to operate the memory circuit 130.

In an embodiment, the signal feeding circuit block 150 is implemented by a self-test circuit block to operate according to the feeding signal FI generated by the test patterns generation circuit 190 in the memory built-in self test mode to perform a memory built-in self test on the memory circuit 130.

More specifically, in the memory built-in self test mode, the feeding multiplexer 155C selects the processed control signal FS to be the feeding control signal FC. Further, in the memory built-in self test mode, the input selection multiplexer 120 selects the feeding control signal FC generated by the signal feeding circuit block 150 to be the memory control signal MS to operate the memory circuit 130 to perform the memory built-in self test on the memory circuit 130.

In order to allow the signal feeding circuit block 150 to operate in the output at-speed test mode, a plurality of test patterns TP are written to the memory circuit 130 corresponding to the output at-speed test mode first.

In an embodiment, the test patterns TP are generated by the test patterns generation circuit 190 according to an analysis performed on the output function circuit block 140. The test patterns TP can be directly written to the memory circuit 130 by the test patterns generation circuit 190. It is appreciated that in other embodiments, the test patterns TP can be written to the memory circuit 130 through the input function circuit block 110 or the signal feeding circuit block 150 implemented by the self-test circuit block by the test patterns generation circuit 190.

Subsequently, in the output at-speed test mode, the feeding multiplexer 155C selects the feeding signal FI to be the feeding control signal FC. As a result, the feeding logic circuit 155B is equivalently bypassed by the feeding multiplexer 155C.

Further, in the output at-speed test mode, the input selection multiplexer 120 selects the feeding control signal FC generated by the signal feeding circuit block 150 to be the memory control signal MS to operate the memory circuit 130.

In an embodiment, the feeding signal FI generated by the test patterns generation circuit 190 corresponding to the output at-speed test mode includes a memory read enable command and a designated read address (not illustrated in the figure) such that the output logic circuit 145A of the output function circuit block 140 receives and processes the output signal OS that includes the test patterns TP to generate the output result OR. The output flip-flop circuit 145B is configured to receive and output the output result OR. The output result OR is further read and verified by the test patterns generation circuit 190.

By using the method described above, the memory circuit 130 is equivalent to be a buffer or a flip-flop such that the signal feeding circuit block 150 directly outputs the feeding signal FI to be the feeding control signal FC serving as the memory control signal MS to operate the memory circuit 130. The output function circuit block 140 receives and processes the output signal OS including the test patterns TP to generate the output result OR. The output at-speed test can thus be performed on the actual signal processing path of the output logic circuit 145A.

In an embodiment, in order to operate the memory apparatus 100 in different modes, the feeding multiplexer 155C and the input selection multiplexer 120 in FIG. 1 and the memory multiplexer 220 in FIG. 2 may be controlled by signals to operate in different modes.

For example, the feeding multiplexer 155C is configured to receive an output at-speed test signal STS to select the processed control signal FS to be the feeding control signal FC when the output at-speed test signal STS is 0 (i.e., not in the output at-speed test mode). The feeding multiplexer 155C selects the feeding signal FI to be the feeding control signal FC when the output at-speed test signal STS is 1 (i.e., in the output at-speed test mode).

The input selection multiplexer 120 is configured to receive an OR logic operation result of the output at-speed test signal STS and a memory built-in self test signal SBS, in which such an OR logic operation result is represented as STS ∥ SBS.

As a result, when the output at-speed test signal STS is 1 (i.e., in the output at-speed test mode) or when the memory built-in self test signal SBS is 1 (i.e., in the memory built-in self test mode), the input selection multiplexer 120 selects the feeding control signal FC to be the memory control signal MS according to the operation result of the logic value 1.

Besides, when the output at-speed test signal STS is 0 (i.e., not in the output at-speed test mode) or when the memory built-in self test signal SBS is 0 (i.e., not in the memory built-in self test mode), the input selection multiplexer 120 operates in the memory operation mode or the scan mode to select the input control signal CI to be the memory control signal MS according to the operation result of the logic value 0.

The memory multiplexer 220 is configured to receive an AND logic operation result of the inverted output at-speed test signal STS and a scan test signal SCS that is represented by !STS && SCS. As a result, when the output at-speed test signal STS is 1 (i.e., in the output at-speed test mode) and when the scan test signal SCS is 0 (i.e., not in the scan test mode), the memory multiplexer 220 selects the read signal RS to be the output signal OS according to the operation result of the logic value 0.

When the output at-speed test signal STS is 0 (i.e., not in the output at-speed test mode) and when the scan test signal SCS is 1 (i.e., in the scan test mode), the memory multiplexer 220 selects the memory control signal MS to be the output signal OS according to the operation result of the logic value 1.

When the output at-speed test signal STS is 0 (i.e., not in the output at-speed test mode) and when the scan test signal SCS is 0 (i.e., not in the scan test mode), the memory multiplexer 220 operates in the memory operation mode and selects the read signal RS to be the output signal OS according to the operation result of the logic value 0.

It is appreciated that the control of the signals described above is merely an example. In practical implementation, each of the multiplexers may switch the operation mode by using other signal control methods. The present invention is not limited thereto.

In the embodiments described above, the condition that the signal feeding circuit block 150 is implemented by the self-test circuit block is used as an example. In an embodiment, the configuration of the signal feeding circuit block 150 can be also applied to the input function circuit block 110, in which the role of the input flip-flop circuit 115A and the input logic circuit 115B correspond to the role of the feeding flip-flop circuit 155A and the feeding logic circuit 155B, and an additional multiplexer is disposed in the input function circuit block 110 to perform selection on the signals before being processed and after being processed by the input logic circuit 115B.

As a result, the input function circuit block 110 may control the memory circuit 130 by directly using a signal before being processed by the input logic circuit 115B in the output at-speed test mode and may access or perform the scan test on the memory circuit by using a signal after being processed by the input logic circuit 115B in the memory operation mode or in the scan test mode.

Further, in the embodiments described above, the condition that the memory circuit 130 is implemented by the integrated test memory is used as an example. In other embodiments, the memory circuit 130 can be implemented by a regular memory that does not include an integrated test configuration. The output at-speed test can still be accomplished by using the same test pattern writing method and the same signal feeding method. The present invention is not limited thereto.

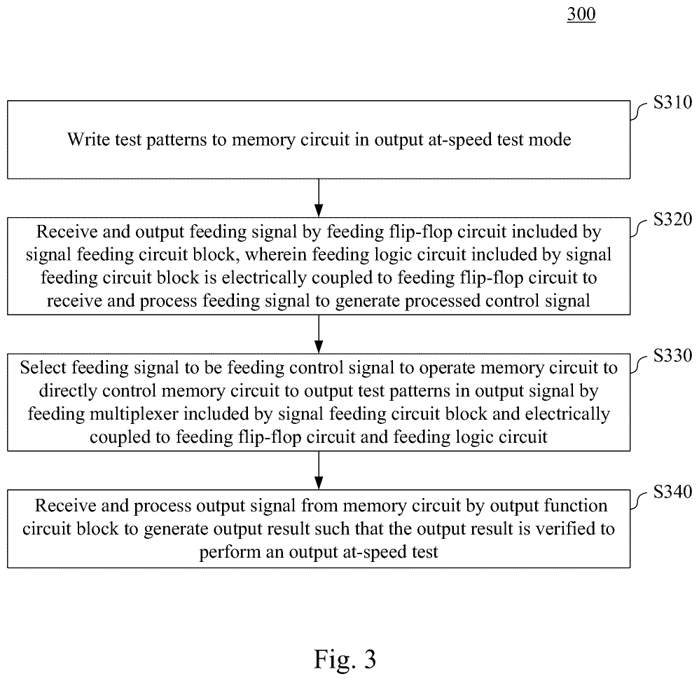

Reference is now made to FIG. 3. FIG. 3 illustrates a flow chart of a memory test method 300 according to an embodiment of the present invention.

Besides the apparatus described above, the present invention further discloses the memory test method 300 that can be used in such as, but not limited to the memory apparatus 100 illustrated in FIG. 1. An embodiment of the memory test method 300 is illustrated in FIG. 3 and includes the steps outlined below.

In step S310, the test patterns are written to the memory circuit 130 in the output at-speed test mode.

In step S320, the feeding signal is received and outputted by the feeding flip-flop circuit included by the signal feeding circuit block, wherein the feeding logic circuit included by the signal feeding circuit block is electrically coupled to the feeding flip-flop circuit to receive and process the feeding signal to generate the processed control signal.

In step S330, the feeding signal is selected to be the feeding control signal to operate the memory circuit to directly control the memory circuit to output the test patterns in the output signal by the feeding multiplexer included by the signal feeding circuit block and electrically coupled to the feeding flip-flop circuit and the feeding logic circuit.

In step S340, the output signal is received and processed from the memory circuit by the output function circuit block to generate the output result that is verified to perform the output at-speed test.

It is appreciated that the embodiments described above are merely an example. In other embodiments, it is appreciated that many modifications and changes may be made by those of ordinary skill in the art without departing, from the spirit of the invention.

In summary, the memory apparatus having at-speed test mechanism and the memory test method of the same treat a memory circuit as a buffer to write test patterns thereto, bypass a feeding logic circuit by using a feeding multiplexer of a signal feeding circuit block and directly output a feeding signal through a feeding flip-flop circuit to control the memory circuit to output the test patterns in an output signal. An output result generated according to the output signal by an output function circuit block is further verified to accomplish the output at-speed test.

The aforementioned descriptions represent merely the preferred embodiments of the present disclosure, without any intention to limit the scope of the present disclosure thereto. Various equivalent changes, alterations, or modifications based on the claims of present disclosure are all consequently viewed as being embraced by the scope of the present disclosure.

What is claimed is:

1. A memory apparatus having at-speed test mechanism, comprising:
a memory circuit;
an output function circuit block configured to receive and process an output signal from the memory circuit to generate an output result; and
a signal feeding circuit block comprising:
a feeding flip-flop circuit configured to receive and output a feeding signal;
a feeding logic circuit electrically coupled to the feeding flip-flop circuit to receive and process the feeding signal to generate a processed control signal; and
a feeding multiplexer electrically coupled to the feeding flip-flop circuit and the feeding logic circuit;
wherein in an output at-speed test mode, a plurality of test patterns are written to the memory circuit, the feeding multiplexer is configured to select the feeding signal to be a feeding control signal to operate the memory circuit to directly control the memory circuit to output the test patterns in the output signal such that the output result is verified to perform an output at-speed test.

2. The memory apparatus of claim 1, wherein the output function circuit block comprises:
a output logic circuit configured to receive and process the output signal to generate the output result; and
a output flip-flop circuit configured to receive and output the output result;
wherein the output at-speed test is configured to verify the output logic circuit.

3. The memory apparatus of claim 1, wherein the signal feeding circuit block is a self-test circuit block, and the feeding multiplexer selects the processed control signal as the feeding control signal in a memory built-in self test (MBIST) mode to operate the memory circuit to perform memory built-in self test on the memory circuit.

4. The memory apparatus of claim 3, further comprising:
an input function circuit block configured to receive an input signal to generate an input control signal; and
an input selection multiplexer configured to:
select the feeding control signal as a memory control signal to operate the memory circuit either in the memory built-in self test mode or in the output at-speed test mode; and
select the input control signal as the memory control signal to operate the memory circuit in a memory operation mode or a scan test mode that comprises an input at-speed test to access the memory circuit or perform a scan test on the memory circuit.

5. The memory apparatus of claim 4, wherein the memory circuit comprises:
a scan flip-flop circuit configured to receive and output the memory control signal;
a memory array electrically coupled to the scan flip-flop circuit and configured to receive the memory control signal through the scan flip-flop circuit and generate a read signal when a read operation is performed on the memory array; and
a memory multiplexer electrically coupled to the scan flip-flop circuit and the memory array, and configured to select the read signal as the output signal in either the memory operation mode or the output at-speed test mode and select the memory control signal outputted by the scan flip-flop circuit as the output signal in the scan test mode.

6. The memory apparatus of claim 1, wherein the signal feeding circuit block is an input function circuit block, and the feeding multiplexer selects the processed control signal as the feeding control signal in a memory operation mode or a scan test mode that comprises an input at-speed test to access the memory circuit or perform a scan test on the memory circuit.

7. The memory apparatus of claim 1, wherein the test patterns are generated by a test patterns generation circuit, the feeding signal comprises a memory read enable command and a designated read address and is generated by the test patterns generation circuit, and the output result is read and verified by the test patterns generation circuit.

8. The memory apparatus of claim 7, wherein the test patterns are written to the memory circuit directly by the test patterns generation circuit or through an input function circuit block or a self-test circuit block by the test patterns generation circuit.

9. A memory test method having at-speed test mechanism, comprising:
writing a plurality of test patterns to a memory circuit in an output at-speed test mode;
receiving and outputting a feeding signal by a feeding flip-flop circuit comprised by a signal feeding circuit block, wherein a feeding logic circuit comprised by the signal feeding circuit block is electrically coupled to the feeding flip-flop circuit to receive and process the feeding signal to generate a processed control signal;
selecting the feeding signal to be a feeding control signal to operate the memory circuit to directly control the memory circuit to output the test patterns in the output signal by a feeding multiplexer comprised by the signal feeding circuit block and electrically coupled to the feeding flip-flop circuit and the feeding logic circuit; and
receiving and processing the output signal from the memory circuit by an output function circuit block to generate an output result such that the output result is verified to perform an output at-speed test.

10. The memory test method of claim 9, further comprising:
receiving and processing the output signal by a output logic circuit comprised by the output function circuit block to generate the output result; and
receiving and outputting the output result by a output flip-flop circuit by the output function circuit block;
wherein the output at-speed test is configured to verify the output logic circuit.

11. The memory test method of claim 9, wherein the signal feeding circuit block is a self-test circuit block, and the memory test method further comprises:
selecting the processed control signal as the feeding control signal in a memory built-in self test mode by the feeding multiplexer to operate the memory circuit to perform memory built-in self test on the memory circuit.

12. The memory test method of claim 11, further comprising:
receiving an input signal to generate an input control signal by an input function circuit block;
selecting the feeding control signal as a memory control signal by an input selection multiplexer to operate the memory circuit either in the memory built-in self test mode or in the output at-speed test mode; and
selecting the input control signal as the memory control signal by the input selection multiplexer to operate the memory circuit in a memory operation mode or a scan test mode that comprises an input at-speed test to access the memory circuit or perform a scan test on the memory circuit.

13. The memory test method of claim 12, further comprising:
receiving and outputting the memory control signal by a scan flip-flop circuit comprised by the memory circuit;
receiving the memory control signal through the scan flip-flop circuit and generating a read signal by a memory array comprised by the memory circuit and electrically coupled to the scan flip-flop circuit when a read operation is performed on the memory array; and
selecting the read signal as the output signal in either the memory operation mode or the output at-speed test mode and selecting the memory control signal outputted by the scan flip-flop circuit as the output signal in the scan test mode by a memory multiplexer comprised by the memory circuit and electrically coupled to the scan flip-flop circuit and the memory array.

14. The memory test method of claim 9, wherein the signal feeding circuit block is an input function circuit block, and the memory test method further comprises:
selecting the processed control signal as the feeding control signal in a memory operation mode or a scan test mode that comprises an input at-speed test by the feeding multiplexer to access the memory circuit or perform a scan test on the memory circuit.

15. The memory test method of claim 9, wherein the test patterns are generated by a test patterns generation circuit, the feeding signal comprises a memory read enable command and a designated read address and is generated by the test patterns generation circuit, and the output result is read and verified by the test patterns generation circuit.

16. The memory test method of claim 15, wherein the test patterns are written to the memory circuit directly by the test patterns generation circuit or through an input function circuit block or a self-test circuit block by the test patterns generation circuit.
